(19) United States
(12) Patent Application Publication
(10) Pub. No.: US 2019/0375944 A1
(43) Pub. Date: Dec. 12, 2019

(54) COMPOSITION FOR FORMING PRIMER LAYER, KIT, PRIMER LAYER, AND LAMINATE

(71) Applicant: FUJIFILM Corporation, Tokyo (JP)

(72) Inventors: Yuichiro GOTO, Haibara-gun (JP); Naoya SHIMOJU, Haibara-gun (JP)

(73) Assignee: FUJIFILM Corporation, Tokyo (JP)

(21) Appl. No.: 16/550,665

(22) Filed: Aug. 26, 2019

Related U.S. Application Data
(63) Continuation of application No. PCT/JP2018/007123, filed on Feb. 27, 2018.

(30) Foreign Application Priority Data
Feb. 28, 2017 (JP) 2017-036864

(51) Int. Cl. C09D 5/00; C08F 22/20; C08F 22/10; C08F 22/14; C09D 135/02; C09D 171/02

(52) U.S. Cl. CPC C09D 5/002; C08F 22/20; C08F 22/105; G03F 7/0002; C09D 135/02; C09D 171/02; C08F 22/14

(57) ABSTRACT

Provided are a composition for forming a primer layer capable of improving wettability of a curable composition for imprinting on a substrate while maintaining imprinting performance, a kit, a primer layer, and a laminate.

The composition for forming a primer layer which is used for forming a primer layer contains: a polymerizable compound having a viscosity of 200 to 2,000 mPa·s at 23° C.; and a solvent, in which a content of the polymerizable compound in a nonvolatile component contained in the composition is greater than or equal to 30 mass %, a content of the solvent in the composition is greater than or equal to 98.0 mass %, and the primer layer is a liquid film in a case where a curable composition for imprinting is applied onto a surface of the primer layer, and the primer layer and the curable composition for imprinting are soluble to each other.

### CROSS-REFERENCE TO RELATED APPLICATIONS

This application is a Continuation of PCT International Application No. PCT/JP2018/007123 filed on Feb. 27, 2018, which claims priority under 35 U.S.C. § 119(a) to Japanese Patent Application No. 2017-036864 filed on Feb. 28, 2017. Each of the above application(s) is hereby expressly incorporated by reference, in its entirety, into the present application.

### BACKGROUND OF THE INVENTION

### 1. Field of the Invention

The present invention relates to a composition for forming a primer layer, a kit, a primer layer, and a laminate. In particular, the present invention relates to a composition for forming a primer layer for imprinting.

### 2. Description of the Related Art

An imprinting method is a method for radiating light through a light-transmitting mold or a light-transmitting substrate, and photohardening a curable composition for imprinting, followed by peeling the mold to transfer a fine pattern to a cured product. Since this method enables imprinting at room temperature, it can be applied to a precision processing field of ultrafine patterns such as production of a semiconductor integrated circuit. In recent years, new developments such as a nanocasting method in which advantages of both methods are combined or a reversal imprinting method in which a three-dimensional lamination structure is produced have been reported.

Here, adhesiveness between a substrate and a curable composition for imprinting accompanied by activation of the imprinting method has become a problem. That is, in the imprinting method, a surface of the substrate is coated with the curable composition for imprinting which is then irradiated with light in a state in which the surface thereof is brought into contact with the mold and hardened, and the mold is peeled off. However, in the step of peeling off the mold, the cured product may be peeled off from the substrate and attached to the mold in some cases. It is considered that this is because adhesiveness between the substrate and the cured product is lower than that between the mold and the cured product. It has been studied that an adhesive layer for imprinting which improves the adhesiveness between the substrate and the cured product is used (JP2009-503139A, JP2014-024322A, and JP2014-192178A) in order to solve such a problem.

### SUMMARY OF THE INVENTION

However, it has been found that, in a case where a curable composition for imprinting is applied onto a surface of an adhesive layer in the related art, filling properties of the curable composition for imprinting may deteriorate in some cases. In particular, in a case where the curable composition for imprinting is applied through an inkjet (U) method, liquid droplets of a curable composition for imprinting 22 are added dropwise onto a surface of an adhesive layer 21 at equal intervals as shown in FIG. 2, for example, the above-described liquid droplets spread on the adhesive layer 21 to form a layer-shaped curable composition for imprinting 22. However, in a case where wettability of the curable composition for imprinting is low, in some cases, the curable composition for imprinting may not spread on the adhesive layer 21 and a portion where the adhesive layer 21 is not filled with the curable composition for imprinting 22 may remain. That is, it is necessary to improve the wettability of the curable composition for imprinting on the adhesive layer 21. In addition, as a matter of course, it is necessary not to degrade the imprinting performance.

An object of the present invention is to improve the wettability of the curable composition for imprinting on the substrate while maintaining the imprinting performance to solve the problem. Specifically, the object of the present invention is to provide a novel composition for forming a primer layer, a kit, a primer layer, and a laminate for solving the above-described problem.

On the basis of the above-described problem, it was found that the above-described problem can be solved using a specific primer layer as an underlayer to be coated with a curable composition for imprinting. Specifically, the above-described problem has been solved by means <1> and preferably means <2> to <14>.

<1> A composition for forming a primer layer which is used for forming a primer layer, the composition comprising: a polymerizable compound having a viscosity of 200 to 2,000 mPa·s at 23° C.; and a solvent, in which a content of the polymerizable compound in a nonvolatile component contained in the composition is greater than or equal to 30 mass %, a content of the solvent in the composition is greater than or equal to 98.0 mass %, and the primer layer is a liquid film in a case where a curable composition for imprinting is applied onto a surface of the primer layer, and the primer layer and the curable composition for imprinting are soluble to each other.

<2> The composition for forming a primer layer according to <1>, in which a surface tension of the polymerizable compound at 23° C. is greater than or equal to 38 mN/m.

<3> The composition for forming a primer layer according to <1> or <2>, in which the polymerizable compound contains an aromatic ring.

<4> The composition for forming a primer layer according to <1> or <2>, in which the polymerizable compound contains two or more aromatic rings in a molecule.

<5> The composition for forming a primer layer according to any one of <1> to <4>, further comprising: a non-polymerizable alkylene glycol compound.

<6> The composition for forming a primer layer according to any one of <1> to <5>, in which a proportion of an alkylene oxide chain in the polymerizable compound is less than or equal to 30 mass %, provided that the proportion of the alkylene oxide chain is a value calculated by (formula weight of alkylene oxide chain in polymerizable compound)/(molecular weight of polymerizable compound)×100.

<7> A kit comprising: the composition for forming a primer layer according to any one of <1> to <6>; and a curable composition for imprinting containing a polymerizable compound.

<8> The kit according to <7>, in which a smallest surface tension at 23° C. of a polymerizable compound among polymerizable compounds contained in the curable composition for imprinting is smaller than a surface tension at 23° C. of at least one kind of polymerizable compounds contained in the composition for forming a primer layer.

<9> The kit according to <7>, in which a smallest surface tension at 23° C. of a polymerizable compound among polymerizable compounds contained in the curable composition for imprinting is smaller than a surface tension at 23° C. of all of polymerizable compounds contained in the composition for forming a primer layer.

<10> The kit according to any one of <7> to <9>, in which a content of a solvent in the curable composition for imprinting is less than or equal to 5 mass % of the composition.

<11> A primer layer formed of the composition for forming a primer layer according to any one of <1> to <6>.

<12> The primer layer according to <11>, in which a thickness of the primer layer is 5 to 20 nm.

<13> A laminate comprising: a primer layer formed of the composition for forming a primer layer according to any one of <1> to <6>; and a layer formed of a curable composition for imprinting which is positioned at a surface of the primer layer and contains a polymerizable compound.

<14> The laminate according to <13>, further comprising: an adhesive layer on a surface of the primer layer on a side opposite to a side where the layer formed of the curable composition for imprinting is positioned.

According to the present invention, it has become possible to improve the wettability of a curable composition for imprinting on a substrate while maintaining the imprinting performance. Specifically, it has become possible to provide a novel composition for forming a primer layer, a kit, a primer layer, and a laminate.

### BRIEF DESCRIPTION OF THE DRAWINGS

FIG. 1 is a schematic view showing each step of a pattern forming method of the present invention.

FIG. 2 is a schematic view showing a state of wet-spreading of a curable composition for imprinting in a case where a surface of a well-known adhesive layer is coated with a curable composition for imprinting through an inkjet method.

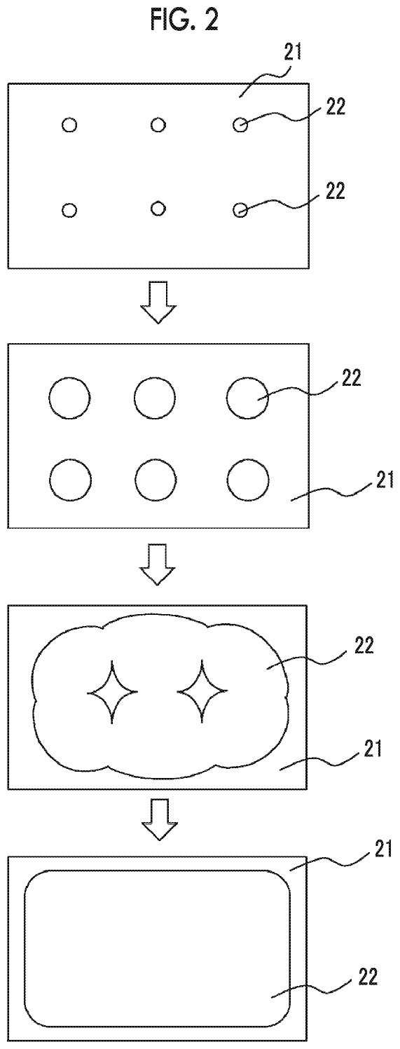

### DESCRIPTION OF THE PREFERRED EMBODIMENTS

Hereinafter, the contents of the present invention will be described in detail. In the present specification, “to” means a range including numerical values denoted before and after “to” as a lower limit value and an upper limit value.

In the present specification, “(meth)acrylate” represents acrylate and methacrylate.

In the present specification, “imprinting” preferably refers to transferring a pattern with a size of 1 nm to 10 mm, and more preferably to transferring (nanoimprinting) a pattern with a size of about 10 nm to 100 μm.

In the notation of a group (atomic group) in the present specification, in a case where it is not described whether the group is substituted or unsubstituted, the group is meant to include and not to include a substituent. For example, an “alkyl group” includes not only an alkyl group having no substituent (unsubstituted alkyl group), but also an alkyl group having a substituent (substituted alkyl group).

In the present specification, “light” includes not only electromagnetic waves or light with a wavelength in regions such as an ultraviolet region, a near ultraviolet region, a far ultraviolet region, a visible region, or an infrared region, but also radiation. Radiation includes, for example, microwaves, electron beams, extreme ultraviolet rays (EUV), and X-rays. In addition, laser beams such as a 248 nm excimer laser, a 193 nm excimer laser, and a 172 nm excimer laser can also be used. For these light beams, monochromatic light (single-wavelength light) passed through an optical filter may be used, or light with a plurality of different wavelengths (composite light) may be used.

The weight-average molecular weight (Mw) in the present invention is measured through gel permeation chromatography (GPC) unless otherwise specified.

The composition for forming a primer layer of the present invention contains: a polymerizable compound having a viscosity of 200 to 2,000 mPa·s at 23° C.; and a solvent, in which a content of the polymerizable compound in a nonvolatile component contained in the composition is greater than or equal to 30 mass %, a content of the solvent in the composition is greater than or equal to 98.0 mass %, and the primer layer is a liquid film in a case where a curable composition for imprinting is applied onto a surface of the primer layer, and the primer layer and the curable composition for imprinting are soluble to each other. By adopting such a configuration, it is possible to improve the wettability of a curable composition for imprinting on a substrate while maintaining the imprinting performance. In particular, a composition which has excellent stability in film thickness and excellent processing resistance and of which a release force is small is obtained.

In addition, the primer layer of the present invention is a liquid film in a case where a curable composition for imprinting is applied onto a surface of the above-described primer layer, and the primer layer and the above-described curable composition for imprinting are soluble to each other. The liquid film in a case where a curable composition for imprinting is applied means that a primer layer in a case where a curable composition for imprinting is applied is a liquid film. In addition, the expression that the primer layer and the curable composition for imprinting are soluble to each other means that primer layer components formed of nonvolatile components of the composition for forming a primer layer and the curable composition for imprinting are soluble at a predetermined proportion. It is preferable that the primer layer components dissolve in the curable composition for imprinting and exist as a part of a pattern laminate after hardening.

That is, it is possible to improve wettability of the curable composition for imprinting by applying a polymerizable compound, in a liquid state, having a viscosity within the above-described ranges and high surface tension immediately below the curable composition for imprinting. Furthermore, even in a case where a part of the composition for forming a primer layer dissolves in the curable composition for imprinting, a polymerizable group of a polymerizable compound contained in the composition for forming a primer layer and a polymerizable group of a polymerizable compound contained in the curable composition for imprinting forms a cross-linked structure. For this reason, it is possible to maintain the pattern strength of an imprinted laminate after hardening and to suppress pattern collapse defects.

In particular, in the present invention, the curable composition for imprinting is preferably used in a case of discrete application such as inkjet (IJ) application.

Hereinafter, the composition for forming a primer layer of the present invention will be described in detail.

<Polymerizable Compound Having Viscosity of 200 to 2,000 mPa·s at 23° C.>

The polymerizable compound used in the present invention has a viscosity of 200 to 2,000 mPa·s at 23° C. The above-described viscosity is preferably greater than or equal to 250 mPa·s and more preferably 300 mPa·s. In addition, the viscosity is preferably less than or equal to 1,500 mPa·s. In a case where the above-described viscosity is below 200 mPa·s, stability of a coating film of a primer layer decreases and the film thickness becomes uneven. Therefore, film aggregation is likely to occur. In a case where the above-described viscosity exceeds 2,000 mPa·s, the effect of improving the wettability of the curable composition for imprinting is reduced.

The surface tension of the polymerizable compound used in the present invention at 23° C. is preferably greater than or equal to 35 mN/m and more preferably greater than or equal to 38 mN/m. The upper limit of the surface tension is not particularly limited, but is, for example, less than or equal to 45 mN/m. By setting the surface tension to be greater than or equal to 35 mN/m, it is possible to further improve wettability of the curable composition for imprinting which will be provided immediately above the primer layer.

The kind of polymerizable group included in the polymerizable compound contained in the composition for forming a primer layer is not particularly specified, but is, for example, an ethylenically unsaturated bond-containing group and an epoxy group and preferably an ethylenically unsaturated bond-containing group. Examples of the ethylenically unsaturated bond-containing group include a (meth)acryloyl group and a vinyl group, more preferably a (meth)acryloyl group, and still more preferably an acryloyl group. In addition, the (meth)acryloyl group is preferably a (meth)acryloyloxy group.

The above-described polymerizable compound may contain only one polymerizable group in a molecule and may contain two or more polymerizable groups in a molecule. Two to six polymerizable groups are preferable, two to five polymerizable groups are more preferable, and two to four polymerizable groups are still more preferable. In the case where the polymerizable compound contains two or more polymerizable groups in a molecule, two or more kinds of polymerizable groups may be contained therein, or two or more polymerizable groups of the same kind may be contained therein.

The polymerizable compound contained in the composition for forming a primer layer preferably contains a ring, more preferably contains an aromatic ring, still more preferably contains two or more aromatic rings in a molecule, and still more preferably contains two to four aromatic rings in a molecule. In a case where the polymerizable compound contains an aromatic ring, the surface tension tends to increase, which can further improve not only the wettability of the curable composition for imprinting, but also etching processing resistance in a case where a part of the composition for forming a primer layer dissolves in the curable composition for imprinting. The aromatic ring contained in the above-described polymerizable compound is preferably a benzene ring.

The above-described polymerizable compound is preferably consisting of only atoms selected from a carbon atom, an oxygen atom, a hydrogen atom, a sulfur atom, and a nitrogen atom, and more preferably consisting of only atoms selected from a carbon atom, an oxygen atom, and a hydrogen atom.

The proportion of an alkylene oxide (AO) chain in the above-described polymerizable compound is preferably less than or equal to 30 mass %, more preferably less than or equal to 20 mass %, and still more preferably less than or equal to 10 mass %. However, the proportion of the alkylene oxide chain is a value calculated by (formula weight of alkylene oxide chain in polymerizable compound)/(molecular weight of polymerizable compound)×100. By setting the proportion of the alkylene oxide (AO) chain to be less than or equal to 30 mass %, it is possible to effectively suppress the curable composition for imprinting from bonding to the surface of a mold after a part of the composition for forming a primer layer dissolves in the curable composition for imprinting, thereby further improving releasability of the curable composition for imprinting.

Specific examples of the polymerizable compounds include polymerizable compounds A-1 to A-7 described in examples to be described below. In addition, methoxypolyethylene glycol (meth)acrylate (BLEMMER PME/AME series manufactured by NOF CORPORATION), polyethylene glycol (meth)acrylate (BLEMMER PE/AE series manufactured by NOF CORPORATION), epoxy ester (EPOXY ESTER M-600A, 40EM, 70EM manufactured by KYOEISHA CHEMICAL Co., LTD.), and the like can also be used. Furthermore, the following compounds can also be used.

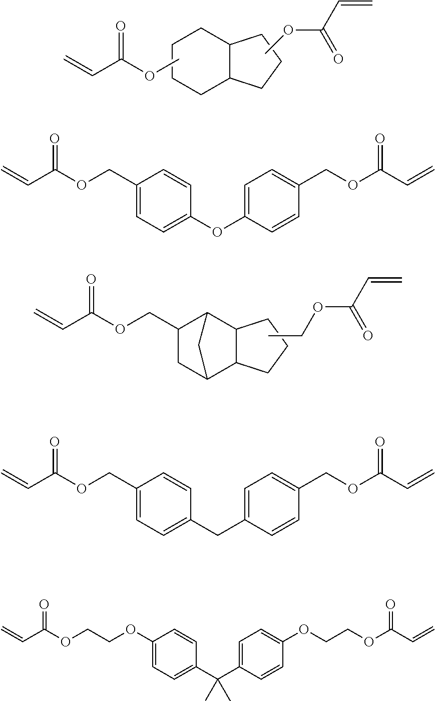

The content of the above-described polymerizable compound contained in the composition for forming a primer layer of the present invention in a nonvolatile component contained in the above-described composition is greater than or equal to 30 mass %, preferably greater than or equal to 50 mass %, more preferably greater than or equal to 70 mass %, and still more preferably greater than or equal to 90 mass %. In a case where the above-described content below 30 mass %, the effect of improving the wettability of the curable composition for imprinting is reduced. In addition, the upper limit value of the content of the above-described polymerizable compound is less than or equal to 100 mass % in a nonvolatile component contained in the above-described composition.

The above-described polymerizable compound contained in the composition for forming a primer layer may be one kind or two or more kinds. In a case where the composition for forming a primer layer contains two or more kinds thereof, the total amount is preferably within the above-described ranges.

<Solvent>

The composition for forming a primer layer of the present invention contains a solvent. In a case where the composition for forming a primer layer contains a solvent, it is possible to perform coating. The solvent is preferably a solvent having any one of an ester group, a carbonyl group, a hydroxyl group, or an ether group.

Examples of preferred solvents include propylene glycol monomethyl ether acetate (PGMEA), ethoxyethyl propionate, cyclohexanone, 2-heptanone, γ-butyrolactone, butyl acetate, propylene glycol monomethyl ether, ethyl lactate, and 4-methyl-2-pentanol. Among these, PGMEA, γ-butyrolactone, cyclohexanone, and 4-methyl-2-pentanol are more preferable, and it is still more preferable to contain at least PGMEA as a solvent.

The content of the above-described solvent in the above-described composition for forming a primer layer is greater than or equal to 98.0 mass % and preferably greater than or equal to 99.0 mass %. In addition, the content of the above-described solvent in the above-described composition is preferably less than or equal to 99.999 mass %.

One kind or two or more kinds of each of the components constituting a primer layer and the solvents may be contained in the composition for forming a primer layer. In a case where the composition for forming a primer layer contains two or more kinds of each of the components constituting a primer layer and the solvents, the total amount is preferably within the above-described ranges.

The composition for forming a primer layer of the present invention may contain other components in addition to the above-described polymerizable compounds and solvents.

<Non-Polymerizable Alkylene Glycol Compound>

The composition for forming a primer layer of the present invention may contain a non-polymerizable alkylene glycol compound. As described above, it is preferable that the proportion of the alkylene oxide (AO) chain in the polymerizable compound contained in the composition for forming a primer layer is less than or equal to 30 mass %. In particular, in a case where a non-polymerizable alkylene glycol compound is blended with the composition for forming a primer layer in addition to the polymerizable compound, the wetting of the curable composition for imprinting tends to be further promoted. In particular, it is desirable that there is alkylene oxide from the viewpoint of the wettability of U liquid droplets (high surface tension). However, in a case where a polymerizable compound containing many alkylene oxide chains is used as a primer layer, the release force when the primer layer dissolves in a resist tends to increase. In the present invention, the above-described point can be effectively adjusted by blending a non-polymerizable alkylene glycol compound with the composition for forming a primer layer.

The non-polymerizable alkylene glycol compound preferably has 3 to 1,000 alkylene glycol constitutional units, more preferably has 4 to 500 alkylene glycol constitutional units, still more preferably has 5 to 100 alkylene glycol constitutional units, and still more preferably has 5 to 50 alkylene glycol constitutional units.

The weight-average molecular weight (Mw) of the non-polymerizable alkylene glycol compound is preferably 150 to 10,000, more preferably 200 to 5,000, still more preferably 300 to 3,000, and still more preferably 300 to 1,000.

The surface tension of the non-polymerizable alkylene glycol compound at 23° C. is preferably greater than or equal to 38 mN/m and more preferably greater than or equal to 40 mN/m. The upper limit of the surface tension is not particularly limited, but is, for example, less than or equal to 48 mN/m. By blending such compounds, it is possible to further improve wettability of the curable composition for imprinting which will be provided immediately above a primer layer.

In a case where a non-polymerizable alkylene glycol compound is contained, the content thereof is less than or equal to 70 mass % of the nonvolatile component of the composition for forming a primer layer, preferably less than or equal to 50 mass % thereof, more preferably less than or equal to 40 mass % thereof, and still more preferably 20 to 35 mass % thereof.

The non-polymerizable alkylene glycol compound may be used alone or in combination of two or more thereof. In a case where two or more kinds of the non-polymerizable alkylene glycol compounds are used, the total amount is preferably within the above-described ranges.

<<Other Polymerizable Compounds>>

The composition for forming a primer layer may contain polymerizable compounds other than the polymerizable compound having a viscosity of 200 to 2,000 mPa·s at 23° C. By blending such compounds, it becomes easier to adjust the physical properties of an imprinted laminate after being hardened which is formed such that the composition for forming a primer layer dissolves in the curable composition for imprinting.

The other polymerizable compounds preferably have a surface tension of less than 35 mN/m at 23° C. The lower limit of the surface tension is not particularly limited, but is, for example, greater than or equal to 30 mPa·s.

The kinds of polymerizable groups included in the other polymerizable compounds is not particularly specified, but is, for example, an ethylenically unsaturated bond-containing group and an epoxy group and preferably an ethylenically unsaturated bond-containing group. Examples of the ethylenically unsaturated bond-containing group include a (meth)acryloyl group and a vinyl group, more preferably a (meth)acryloyl group, and still more preferably an acryloyl group. In addition, the (meth)acryloyl group is preferably a (meth)acryloyloxy group.

The above-described polymerizable compounds may contain only one polymerizable group in a molecule and may contain two or more polymerizable groups in a molecule. Two to six polymerizable groups are preferable, two to five polymerizable groups are more preferable, and two to four polymerizable groups are still more preferable. In the case where the polymerizable compound contains two or more polymerizable groups in a molecule, two or more kinds of polymerizable groups may be contained therein, or two or more polymerizable groups of the same kind may be contained therein.

Specific examples of such other polymerizable compounds include a polymerizable compound (particularly, a first group and a second group of exemplified compounds of monofunctional polymerizable compounds of a first embodiment, and exemplified compounds of monofunctional polymerizable compounds and a first group and a second group of exemplified compounds of polyfunctional polymerizable compounds of a second embodiment) which may be blended with a curable composition for imprinting to be described below, trimethylol tripropane tri(meth)acrylate, and pentaerythritol tri(meth)acrylate.

In a case where the other polymerizable compounds are contained, the contents thereof are less than or equal to 70 mass % of the nonvolatile component of the composition for forming a primer layer, preferably less than or equal to 60 mass % thereof, and more preferably less than or equal to 55 mass % thereof. In addition, the above-described contents are preferably greater than or equal to 10 mass % of the nonvolatile component of the composition for forming a primer layer, more preferably greater than or equal to 20 mass % thereof, and still more preferably 30 mass % thereof.

The other polymerizable compounds may be used alone or in combination of two or more thereof. In a case where two or more kinds of the polymerizable compounds are used, the total amount is preferably within the above-described ranges.

The composition for forming a primer layer may contain a photopolymerization initiator, a thermal polymerization initiator, a sensitizer, an antioxidant, a polymerization inhibitor, a defoamer, and the like within the scope not departing from the gist of the present invention in addition to the above.

The composition for forming a primer layer of the present invention may contain a polymerization initiator, but can also have a configuration in which a polymerization initiator is not substantially contained. The expression “does not substantially contain” means that the content is less than or equal to 1 mass % of the total amount of the nonvolatile component contained in the composition for forming a primer layer, and it is preferable that the content is less than or equal to 0.1 mass %.

In addition, in a case where the composition for forming a primer layer contains a nonvolatile component in addition to the polymerizable compound having a viscosity of 200 to 2,000 mPa·s at 23° C., the viscosity of the nonvolatile component is 200 to 2,000 mPa·s at 23° C.

Furthermore, it is preferable that the composition for forming a primer layer of the present invention does not substantially contain components other than the above-described polymerizable compound having a predetermined viscosity, the above-described solvent, the above-described non-polymerizable alkylene glycol compound, and the other polymerizable compounds. The expression “does not substantially contain” means that the contents of other components are less than or equal to 1 mass % of the nonvolatile component of the composition for forming a primer layer.

The composition for forming a primer layer of the present invention preferably contains 0.001 to 2.0 mass % of components, such as a polymerizable compound, constituting a primer layer and 98.0 to 99.999 mass % of a solvent, and more preferably contains 0.05 to 1.0 mass % of components constituting a primer layer and 99.0 to 99.5 mass % of a solvent.

It is possible to use a well-known storage container in the related art as a storage container of the composition for forming a primer layer used in the present invention. In addition, it is preferable to use a multilayer bottle obtained by forming the inner wall of a container with 6 types and 6 layers of resins or a bottle obtained by forming 6 kinds of resins into a 7-layer structure as the storage container in order to suppress mixing of impurities into a raw material or a composition. Examples of such a container include containers disclosed in JP-2015-123351A.

Next, a kit of the present invention will be described.

A kit of the present invention contains the composition for forming a primer layer and a curable composition for imprinting containing a polymerizable compound. The composition for forming a primer layer is synonymous with the composition for forming a primer layer, and its preferred range is also the same.

In the present invention, a smallest surface tension at 23° C. of a polymerizable compound among polymerizable compounds contained in the curable composition for imprinting preferably is smaller than a surface tension at 23° C. of at least one kind of polymerizable compound contained in the composition for forming a primer layer. Furthermore, in the present invention, a smallest surface tension at 23° C. of a polymerizable compound among polymerizable compounds contained in the above-described curable composition for imprinting is smaller than a surface tension at 23° C. of all polymerizable compounds contained in the composition for forming a primer layer. The difference in the surface tension of the polymerizable compounds contained in the above-described composition for forming a primer layer and the polymerizable compounds contained in the above-described curable composition for imprinting at 23° C. is preferably greater than or equal to 0.1 mN/m, more preferably greater than or equal to 1.0 mN/m, still more preferably greater than or equal to 3.0 mN/m, and still more preferably greater than or equal to 4.0 mN/m. The upper limit value of the difference in the surface tension can be set to be, for example, less than or equal to 20 mN/m, less than or equal to 15 mN/m, and less than or equal to 12 mN/m.

<Curable Composition for Imprinting>

Next, the curable composition for imprinting used in the present invention will be described.

The curable composition for imprinting used in the present invention is not particularly limited as long as it contains a polymerizable compound, and a well-known curable composition for imprinting can be used.

In the present invention, it is preferable that the viscosity of the curable composition for imprinting is designed to be low and the surface tension is designed to be high so as to enable high-speed filling into a mold pattern using a capillary force.

Specifically, the viscosity of the curable composition for imprinting at 23° C. is preferably less than or equal to 20.0 mPa·s, more preferably less than or equal to 15.0 mPa·s, and still more preferably less than or equal to 11.0 mPa·s. The lower limit value of the above-described viscosity is not particularly limited, but can be set to be, for example, greater than or equal to 5.0 mPa·s.

In addition, the surface tension of the curable composition for imprinting at 23° C. is preferably greater than or equal to 30 mN/m and more preferably greater than or equal to 32 mN/m. In a case where a curable composition for imprinting with a high surface tension is used, the capillary force increases, which enables high-speed filling of a mold pattern with the curable composition for imprinting. The upper limit value of the above-described surface tension is not particularly limited, but is preferably less than or equal to 40 mN/m and more preferably less than or equal to 38 mN/m from the viewpoint of imparting inkjet suitability.

In the present invention, use of a predetermined primer layer is highly meaningful from the viewpoint of improving wettability of a curable composition for imprinting with a high surface tension which has poor wettability on an adhesive layer while having a high capillary force and good filling properties in a mold pattern.

The surface tension of curable composition for imprinting at 23° C. is measured according to a method to be described in examples below.

In the present invention, the content of a solvent in the curable composition for imprinting is preferably less than or equal to 5 mass %, more preferably less than or equal to 3 mass %, and still more preferably less than or equal to 1 mass % with respect to the above-described composition.

In addition, it is possible to employ an aspect in which the curable composition for imprinting used in the present invention does not substantially contain a polymer (polymer having a weight-average molecular weight of preferably greater than 1,000, more preferably greater than 2,000, and still more preferably greater than or equal to 10,000). The expression “does not substantially contain a polymer” means, for example, that the content of a polymer is less than or equal to 0.01 mass % of the curable composition for imprinting and preferably less than or equal to 0.005 mass %. It is more preferable that the curable composition for imprinting contains no polymer at all.

<<Polymerizable Compound>>

The polymerizable compound contained in the curable composition for imprinting used in the present invention may be a monofunctional polymerizable compound or a polyfunctional polymerizable compound, or a mixture of both compounds. In addition, it is preferable that at least a part of a polymerizable compound contained in the curable composition for imprinting is a liquid at 23° C. and it is more preferable that greater than or equal to 15 mass % of a polymerizable compound contained in the curable composition for imprinting is a liquid at 23° C.

In addition, the surface tension of the polymerizable compound contained in the curable composition for imprinting at 23° C. is preferably greater than or equal to 25 mN/m and more preferably greater than or equal to 29 mN/m. In addition, the surface tension thereof is preferably less than or equal to 45 mN/m and more preferably less than or equal to 41 mN/m. In a case where the curable composition for imprinting contains two or more kinds of polymerizable compounds, it is preferable that at least one kind of polymerizable compound in the composition satisfies the above-described surface tension and it is more preferable that greater than or equal to 90 mass % of the total polymerizable compounds in the composition satisfies the above-described surface tension.

The type of monofunctional polymerizable compound used in the curable composition for imprinting is not particularly defined as long as the type thereof does not depart from the gist of the present invention.

The molecular weight of the monofunctional polymerizable compound used in the curable composition for imprinting is preferably greater than or equal to 100, more preferably greater than or equal to 200, and still more preferably greater than or equal to 220. The molecular weight is preferably less than or equal to 1,000, more preferably less than or equal to 800, still more preferably less than or equal to 300, and particularly preferably less than or equal to 270. In a case where the lower limit value of the molecular weight is set to be greater than or equal to 100, there is a tendency that it is possible to suppress the volatility. In a case where the upper limit value of the molecular weight is set to be less than or equal to 1,000, there is a tendency that it is possible to reduce the viscosity.

The boiling point of the monofunctional polymerizable compound used in the curable composition for imprinting at 667 Pa is preferably greater than or equal to 85° C., more preferably greater than or equal to 110*C, and still more preferably greater than or equal to 130° C. By setting the boiling point at 667 Pa to be greater than or equal to 85° C., it is possible to suppress the volatility. The upper limit value of the boiling point is not particularly specified, but the boiling point at 667 Pa can be set, for example, to be less than or equal to 200° C.

The kind of polymerizable group included in the monofunctional polymerizable compound used in the curable composition for imprinting is not particularly specified, but is, for example, an ethylenically unsaturated bond-containing group and an epoxy group and preferably an ethylenically unsaturated bond-containing group. Examples of the ethylenically unsaturated bond-containing group include a (meth)acryloyl group and a vinyl group, more preferably a (meth)acryloyl group, and still more preferably an acryloyl group. In addition, the (meth)acryloyl group is preferably a (meth)acryloyloxy group.

The kinds of atoms constituting the monofunctional polymerizable compound used in the curable composition for imprinting is not particularly specified, but the monofunctional polymerizable compound thereof is preferably constituted of only atoms selected from carbon atoms, oxygen atoms, hydrogen atoms, and halogen atoms, and is more preferably constituted of only atoms selected from carbon atoms, oxygen atoms, and hydrogen atoms.

The preferred first embodiment of the monofunctional polymerizable compound used in the curable composition for imprinting is a compound having a linear or branched hydrocarbon chain having 4 or more carbon atoms.

The hydrocarbon chain in the present invention represents an alkyl chain, an alkenyl chain, and an alkynyl chain, preferably an alkyl chain and an alkenyl chain, and more preferably an alkyl chain.

In the present invention, the alkyl chain represents an alkyl group and an alkylene group. Similarly, the alkenyl chain represents an alkenyl group and an alkenylene group, and the alkynyl chain represents an alkynyl group and an alkynylene group. Among these, a linear or branched alkyl group or alkenyl group is more preferable, a linear or branched alkyl group is still more preferable, and a linear alkyl group is still more preferable.

The above-described linear or branched hydrocarbon chain (preferably, alkyl group) has 4 or more carbon atoms, preferably has 6 or more carbon atoms, more preferably has 8 or more carbon atoms, still more preferably 10 or more carbon atoms, and particularly preferably 12 or more carbon atoms. The upper limit value of the number of carbon atoms is not particularly specified, but the number of carbon atoms can be set, for example, to be less than or equal to 25.

The above-described linear or branched hydrocarbon chain may contain an ether group (—O—), but preferably has no ether group from the viewpoint of improving the releasability.

By using a relatively small addition amount of such a monofunctional polymerizable compound having a hydrocarbon chain, the elasticity of a cured product (pattern) is reduced and the releasability improves. In addition, in a case where a monofunctional polymerizable compound having a linear or branched alkyl group is used, the interfacial energy between a mold and a cured product (pattern) is reduced, and therefore, it is possible to further improve the releasability.

Examples of a preferred hydrocarbon group included in the monofunctional polymerizable compound used in the curable composition for imprinting include (1) to (3).

(1) Linear alkyl groups having 8 or more carbon atoms

(2) Branched alkyl groups having 10 or more carbon atoms

(3) Alicyclic or Aromatic Ring Substituted with Linear or Branched Alkyl Group Having 5 or More Carbon Atoms

(1) Linear Alkyl Groups Having 8 or More Carbon Atoms

Among the linear alkyl groups having 8 or more carbon atoms, branched alkyl groups having 10 or more carbon atoms are more preferable, branched alkyl groups having 11 or more carbon atoms are still more preferable, and branched alkyl groups having 12 or more carbon atoms are particularly preferable. In addition, linear alkyl groups having 20 or less carbon atoms are preferable, linear alkyl groups having 18 or less carbon atoms are more preferable, linear alkyl groups having 16 or less carbon atoms are still more preferable, and linear alkyl groups having 14 or less carbon atoms are particularly preferable.

(2) Branched Alkyl Groups Having 10 or More Carbon Atoms

Among the above-described branched alkyl groups having 10 or more carbon atoms, branched alkyl groups having 10 to 20 carbon atoms are preferable, branched alkyl groups having 10 to 16 carbon atoms are more preferable, branched alkyl groups having 10 to 14 carbon atoms are still more preferable, and branched alkyl groups having 10 to 12 carbon atoms are particularly preferable.

(3) Alicyclic or Aromatic Ring Substituted with Linear or Branched Alkyl Group Having 5 or More Carbon Atoms

The linear or branched alkyl group having 5 or more carbon atoms is more preferably a linear alkylene group. The number of carbon atoms in the above-described alkyl group is still more preferably 6 or more, still more preferably 7 or more, and still more preferably 8 or more. The number of carbon atoms in the alkyl group is preferably 14 or less, more preferably 12 or less, and still more preferably 10 or less.

A ring of an alicyclic or aromatic ring may be a monocyclic ring or a fused ring, but is preferably a monocyclic ring. In a case where the ring thereof is a fused ring, the number of rings is preferably 2 or 3. The ring is preferably a 3- to 8-membered ring, more preferably a 5- to 6-membered ring, and still more preferably a 6-membered ring. In addition, the ring is an alicyclic ring or an aromatic ring, but is preferably an aromatic ring. Specific examples of the ring include a cyclohexane ring, a norbornane ring, an isobornane ring, a tricyclodecane ring, a tetracyclododecane ring, an adamantane ring, a benzene ring, a naphthalene ring, an anthracene ring, and a fluorene ring, among which a cyclohexane ring, a tricyclodecane ring, an adamantane ring, and a benzene ring are more preferable and a benzene ring is still more preferable.

The monofunctional polymerizable compound used in the curable composition for imprinting is preferably a compound in which a linear or branched hydrocarbon chain having 4 or more carbon atoms is directly bonded to a polymerizable group or through a linking group, and is more preferably a compound in which any one of the above-described (1) to (3) is directly bonded to a polymerizable group. Examples of the linking group include —O—, —C(═O)—, —CH₂—, or a combination thereof. Linear alkyl (meth)acrylate in which a (1) linear alkyl group having 8 or more carbon atoms is directly bonded to a (meth)acryloyloxy group is particularly preferable as the monofunctional polymerizable compound used in the present invention.

Examples of the monofunctional polymerizable compound of the first embodiment include the following first group and second group. However, it goes without saying that the present invention is not limited thereto. In addition, the first group is more preferable than the second group.

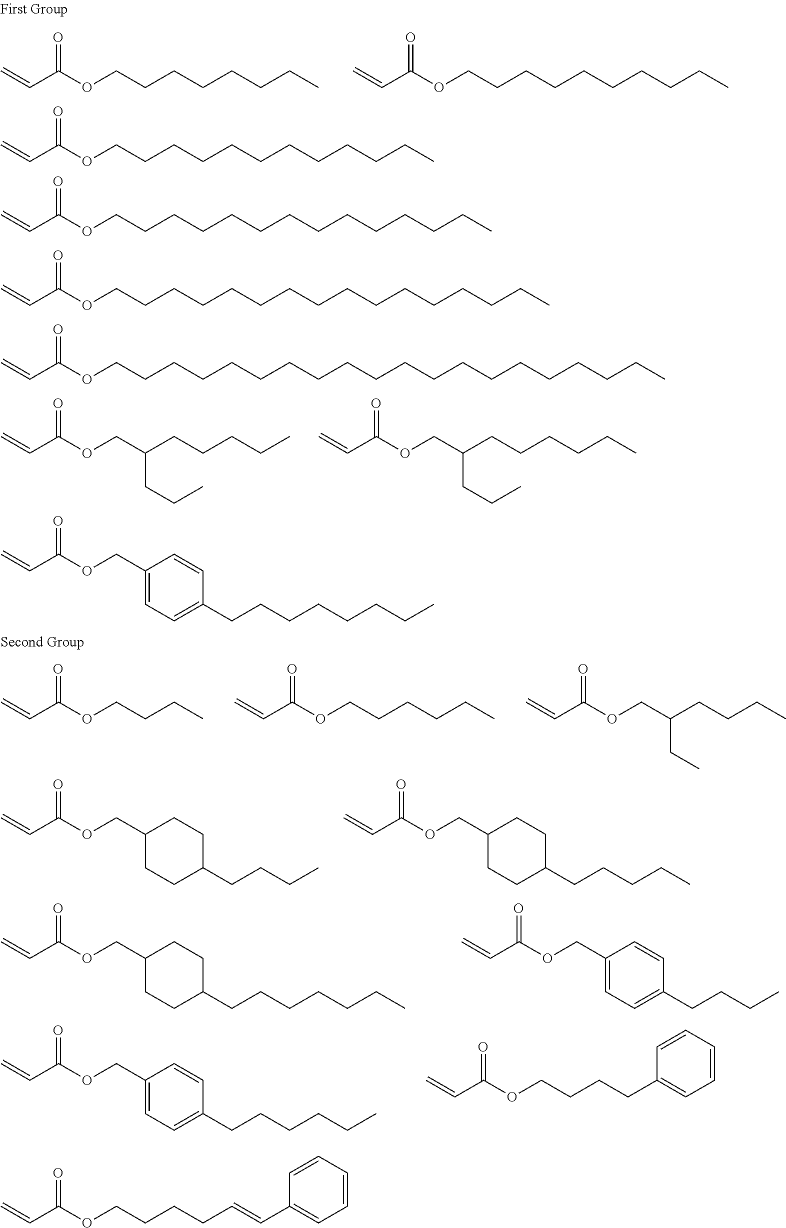

The preferred second embodiment of the monofunctional polymerizable compound used in the curable composition for imprinting is a compound having a cyclic structure. The cyclic structure is preferably a 3- to 8-membered monocyclic ring or a fused ring. The number of rings constituting the above-described fused ring is preferably 2 or 3. The cyclic structure is more preferably a 5- to 6-membered ring and still more preferably a 6-membered ring. In addition, a monocyclic ring is more preferable.

The number of cyclic structures in a molecule of a polymerizable compound may be 1 or 2 or more, but is preferably 1 or 2 and more preferably 1. In a case of a fused ring, the fused ring is considered as a cyclic structure.

Examples of the monofunctional polymerizable compound of the second embodiment include the following compounds. However, it goes without saying that the present invention is not limited thereto.

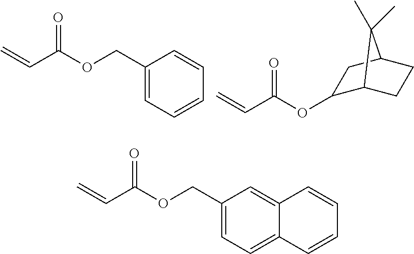

In the present invention, a monofunctional polymerizable compound other than the above-described monofunctional polymerizable compound may be used as long as it does not depart from the gist of the present invention. An example thereof includes a monofunctional polymerizable compound among the polymerizable compounds disclosed in JP2014-170949A, and the contents thereof are included in the present specification.

In a case where the curable composition for imprinting contains a monofunctional polymerizable compound, the content of the monofunctional polymerizable compound used in the curable composition for imprinting with respect to the total polymerizable compound in the curable composition for imprinting is preferably greater than or equal to 6 mass %, more preferably greater than or equal to 8 mass %, still more preferably greater than or equal to 10 mass %, and particularly preferably greater than or equal to 12 mass %. In addition, the above-described content is preferably less than or equal to 60 mass %, and may be less than or equal to 55 mass %.

Only one kind or two or more kinds of monofunctional polymerizable compounds may be contained in the present invention. In a case where two or more kinds of monofunctional polymerizable compounds are contained, the total amount is preferably within the above-described ranges.

On the other hand, the polyfunctional polymerizable compound used in the curable composition for imprinting is not particularly limited, but preferably contains at least one of an alicyclic ring or an aromatic ring and more preferably contains an aromatic ring. In some cases, a compound containing at least one of an alicyclic ring or an aromatic ring may be referred to as a ring-containing polyfunctional polymerizable compound in the description below. By using the ring-containing polyfunctional polymerizable compound in the present invention, it is possible to more effectively suppress etching processing resistance, particularly breakage of a pattern after etching. It is estimated that this is because an etching selection ratio with a processing object (for example, Si, Al, Cr, or an oxide thereof) in a case of etching processing improves.

The molecular weight of the ring-containing polyfunctional polymerizable compound used in the curable composition for imprinting is preferably less than or equal to 1,000, more preferably less than or equal to 800, still more preferably less than or equal to 500, and still more preferably less than or equal to 350. In a case where the upper limit value of the molecular weight is set to be less than or equal to 1,000, there is a tendency that it is possible to reduce the viscosity.

The lower limit value of the molecular weight is not particularly specified, but the molecular weight can be set, for example, to be greater than or equal to 200.

The number of polymerizable groups contained in the ring-containing polyfunctional polymerizable compound used in the curable composition for imprinting is 2 or more, preferably 2 to 7, more preferably 2 to 4, still more preferably 2 or 3, and particularly preferably 2.

The kind of polymerizable group included in the ring-containing polyfunctional polymerizable compound used in the curable composition for imprinting is not particularly specified, but is, for example, an ethylenically unsaturated bond-containing group and an epoxy group and preferably an ethylenically unsaturated bond-containing group. Examples of the ethylenically unsaturated bond-containing group include a (meth)acryloyl group and a vinyl group, more preferably a (meth)acryloyl group, and still more preferably an acryloyl group. In addition, the (meth)acryloyl group is preferably a (meth)acryloyloxy group. Two or more kinds of polymerizable groups may be contained in one molecule, or two or more polymerizable groups of the same kind may be contained therein.

The kinds of atoms constituting the ring-containing polyfunctional polymerizable compound used in the curable composition for imprinting is not particularly specified, but the polyfunctional polymerizable compound thereof is preferably constituted of only atoms selected from carbon atoms, oxygen atoms, hydrogen atoms, and halogen atoms, and is more preferably constituted of only atoms selected from carbon atoms, oxygen atoms, and hydrogen atoms.

The ring contained in the ring-containing polyfunctional polymerizable compound used in the curable composition for imprinting may be a monocyclic ring or a fused ring, but it is preferably a monocyclic ring. In a case where the ring thereof is a fused ring, the number of rings is preferably 2 or 3. The ring is preferably a 3- to 8-membered ring, more preferably a 5- to 6-membered ring, and still more preferably a 6-membered ring. In addition, the ring may be an alicyclic ring or an aromatic ring, but is preferably an aromatic ring. Specific examples of the ring include a cyclohexane ring, a norbornane ring, an isobornane ring, a tricyclodecane ring, a tetracyclododecane ring, an adamantane ring, a benzene ring, a naphthalene ring, an anthracene ring, and a fluorene ring, among which a cyclohexane ring, a tricyclodecane ring, an adamantane ring, and a benzene ring are more preferable and a benzene ring is still more preferable.

The number of rings in the ring-containing polyfunctional polymerizable compound used in the curable composition for imprinting may be 1 or 2 or more, but is preferably 1 or 2 and more preferably 1. In a case of a fused ring, it is considered that the number of fused rings is 1.

The ring-containing polyfunctional polymerizable compound used in the curable composition for imprinting is preferably represented by (polymerizable group)-(single bond or divalent linking group)-(divalent group having ring)-(single bond or a divalent linking group)-(polymerizable group). Here, as the linking group, an alkylene group is more preferable, and an alkylene group having 1 to 3 carbon atoms is more preferable.

The ring-containing polyfunctional polymerizable compound used in the curable composition for imprinting is preferably represented by Formula (1).

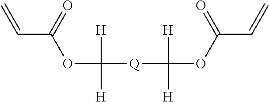

In Formula (1), Q represents a divalent group having an alicyclic ring or an aromatic ring.

The preferred range of an alicyclic ring or an aromatic ring in Q is the same as the above.

Examples of the polyfunctional polymerizable compound used in the curable composition for imprinting include the following first group and second group. However, it goes without saying that the present invention is not limited thereto. The first group is more preferable.

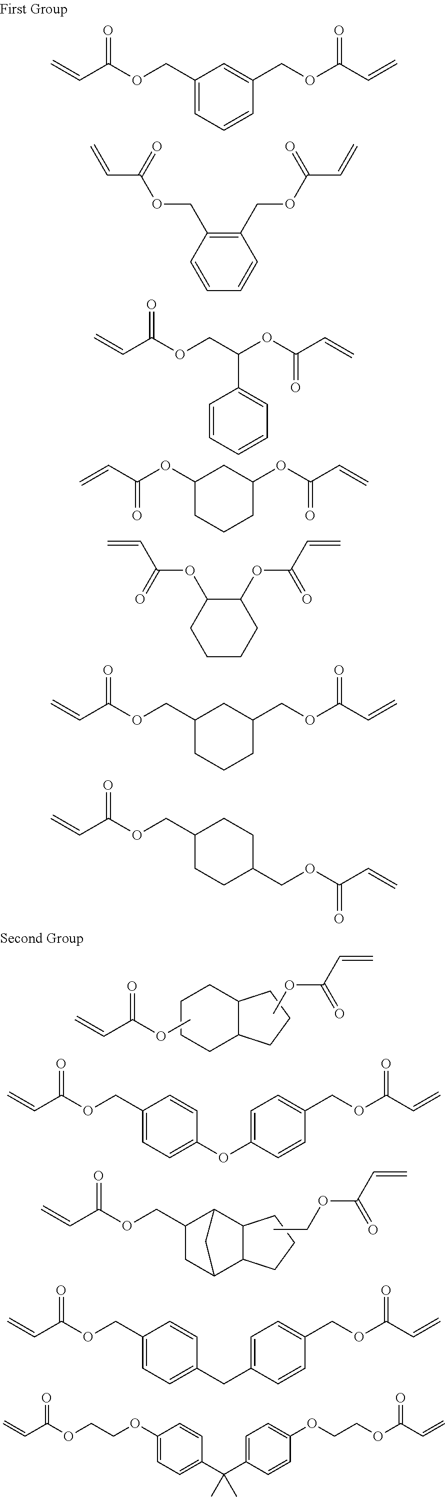

The curable composition for imprinting may contain other polyfunctional polymerizable compounds besides the above-described ring-containing polyfunctional polymerizable compound.

Examples of the other polyfunctional polymerizable compounds used in the curable composition for imprinting include polyfunctional polymerizable compounds having no ring among the polymerizable compounds disclosed in JP2014-170949A, and the contents thereof are included in the present specification. More specifically, for example, the following compounds are exemplified.

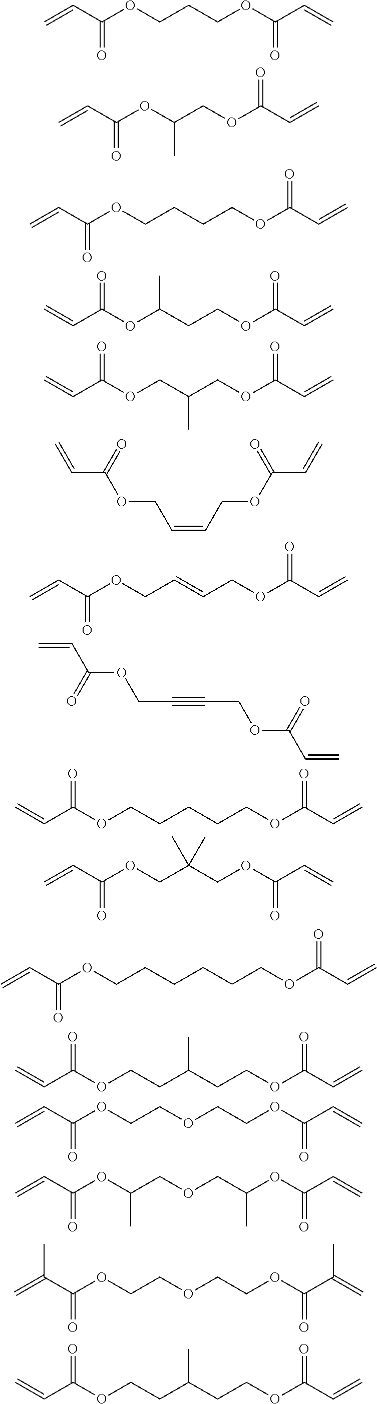

The polyfunctional polymerizable compound with respect to the total polymerizable compound is preferably contained in the curable composition for imprinting in an amount of greater than or equal to 30 mass %, more preferably greater than or equal to 45 mass %, still more preferably greater than or equal to 50 mass %, and still more preferably greater than or equal to 55. The polyfunctional polymerizable compound may be contained therein in an amount of greater than or equal to 60 mass % or an amount of greater than or equal to 70 mass %. In addition, the upper limit value is preferably less than 95 mass %, more preferably less than or equal to 90 mass %, and can also be set to be less than or equal to 85 mass %. By particularly setting the content of the above-described ring-containing polyfunctional polymerizable compound to be greater than or equal to 30 mass % of the total polymerizable compound, the etching selection ratio with a processing object (for example, Si, Al, Cr, or an oxide thereof) in a case of etching processing improves, and therefore, it is possible to suppress breakage of a pattern after etching processing.

The curable composition for imprinting may contain only one kind of polyfunctional polymerizable compound or two or more kinds of polyfunctional polymerizable compounds. In a case where two or more kinds of polyfunctional polymerizable compounds are contained, the total amount is preferably within the above-described ranges.

In the curable composition for imprinting used in the present invention, it is preferable that greater than or equal to 85 mass % of the composition is the polymerizable compound, it is more preferable that greater than or equal to 90 mass % of the composition is the polymerizable compound, and it is still more preferable that greater than or equal to 93 mass % of the composition is the polymerizable compound.

<Other Components>

An additive other than the polymerizable compound may be blended with the curable composition for imprinting. An example of the other additive includes a photopolymerization initiator. Furthermore, the curable composition for imprinting may contain a sensitizer, a releasing agent, a surfactant, an antioxidant, a polymerization inhibitor, a solvent, and the like. Specific examples thereof include each component described in examples to be described below.

In addition, each component disclosed in JP2013-036027A, JP2014-090133A, and JP2013-189537A can be used as a photopolymerization inhibitor, a sensitizer, a releasing agent, an antioxidant, a polymerization inhibitor, a solvent, and the like. The disclosures of the above-described gazettes can also be referred to for the content and the like.

Specific examples of the curable composition for imprinting that can be used in the present invention include compositions to be described in examples below, and compositions disclosed in JP2013-036027A, JP2014-090133A, and JP2013-189537A, and the contents thereof are incorporated into the present specification. In addition, the disclosures of the above-described publications can also be referred to for a method for preparing a curable composition for imprinting and forming and a method for forming a film (pattern forming layer), and the contents thereof are incorporated into the present specification.

It is possible to use a well-known storage container in the related art as a storage container of the curable composition for forming an adhesive film used in the present invention. In addition, it is preferable to use a multilayer bottle obtained by forming the inner wall of a container with 6 types and 6 layers of resins or a bottle obtained by forming 6 kinds of resins into a 7-layer structure as the storage container in order to suppress mixing of impurities into a raw material or a composition. Examples of such a container include containers disclosed in JP-2015-123351A.

Next, a laminate of the present invention will be described.

The laminate of the present invention is a laminate including: a primer layer formed of the above-described composition for forming a primer layer; and a layer formed of a curable composition for imprinting which is positioned at a surface of the above-described primer layer and contains a polymerizable compound. Furthermore, the above-described laminate preferably includes an adhesive layer on a surface of the primer layer on a side opposite to a side where the layer formed of the curable composition for imprinting is positioned. The details of the composition for forming a primer layer and the curable composition for imprinting are as described above and preferred ranges thereof are also the same.

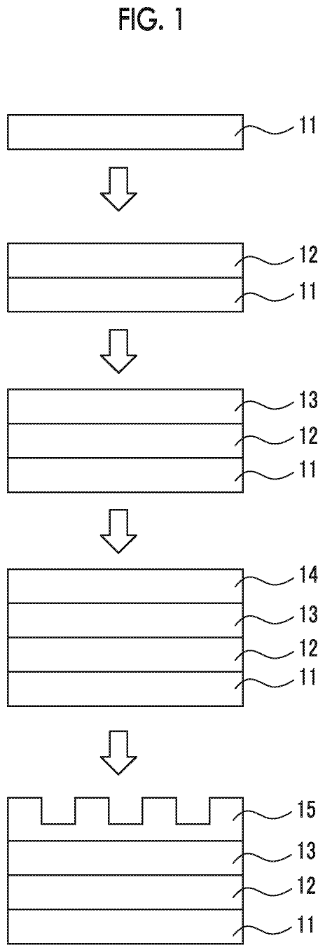

Hereinafter, the method for forming a pattern (pattern forming method) using the composition for forming a primer layer of the present invention will be described with reference to FIG. 1. Needless to say, the configuration of the present invention is not limited to FIG. 1.

<Step of Forming Adhesive Layer on Substrate>

In the present invention, a primer layer may be formed directly on the surface of a substrate, but is preferably formed on the surface of an adhesive layer provided on a substrate. Accordingly, the pattern forming method of the present invention preferably includes a step of forming an adhesive layer on a substrate. However, in a case of using a prepared substrate with an adhesive layer formed thereon in advance, this step is not always indispensable.

In the embodiment shown in FIG. 1, an adhesive layer 12 is formed on a substrate 11. Although the adhesive layer 12 is formed on the surface of the substrate 11 in FIG. 1, another layer may be formed between the substrate 11 and the adhesive layer 12. For example, a case where the surface of the substrate 11 is subjected to a surface treatment is conceivable.

The material of the substrate is not particularly limited, and a disclosure of paragraph 0103 of JP 2010-109092A (the publication number of its corresponding US application is US2011/0199592) can be referred to, and the contents thereof are incorporated in the present specification. In addition to the above, examples thereof include a sapphire substrate, a silicon carbide substrate, a gallium nitride substrate, an aluminum substrate, an amorphous aluminum oxide substrate, a polycrystalline aluminum oxide substrate, and a substrate made of GaAsP, GaP, AlGaAs, InGaN, GaN, AlGaN, ZnSe, AlGaInP, or ZnO. Examples of specific materials of a glass substrate include aluminosilicate glass, aluminoborosilicate glass, and barium borosilicate glass. In the present invention, a silicon substrate is preferable.

The lower limit value of the thickness of an adhesive layer is preferably greater than or equal to 0.1 nm, more preferably greater than or equal to 0.5 nm, and still more preferably greater than or equal to 1 nm. In addition, the upper limit value of the thickness of an adhesive layer is preferably less than or equal to 20 nm, more preferably less than or equal to 15 nm, and still more preferably less than or equal to 10 nm.

The adhesive layer is usually formed by applying a composition for forming an adhesive layer onto a substrate. More specifically, after applying a composition for forming an adhesive layer onto a substrate, a solvent is volatilized (dried) using heat or through light irradiation, and/or the adhesive layer is hardened to form a thin film. The method for applying a composition for forming an adhesive layer is not particularly limited, and a disclosure of paragraph 0102 of JP 2010-109092A (the publication number of its corresponding US application is US2011/0199592) can be referred to, and the contents thereof are incorporated in the present specification. In the present invention, a spin coating method or an inkjet method is preferable.

A composition containing a solvent and a component constituting an adhesive layer is preferable as the composition for forming an adhesive layer.

The component constituting an adhesive layer is preferably a resin, more preferably a resin containing an ethylenically unsaturated group, and still more preferably an acrylic resin having an ethylenically unsaturated group in a side chain. Specific examples of a resin as a component constituting an adhesive layer include resins (A) and (A2) disclosed in paragraphs 0017 to 0057 disclosed in JP2014-024322A. The weight-average molecular weight of a resin is preferably 3,000 to 25,000. In addition, the component constituting an adhesive layer may contain an additive in addition to the resin. However, in the component constituting an adhesive layer of the present invention, it is preferable that greater than or equal to 70 mass % is a resin and it is more preferable that greater than or equal to 80 mass % is a resin.

In order to secure the stability of a primer layer, at least one kind of the component constituting an adhesive layer preferably includes: a component constituting a primer layer; and a functional group capable of forming at least one of a hydrogen bond or an interionic interaction. Examples of the above-described functional group include a hydroxyl group, an amino group, a carbonyl group, and a carboxyl group. Such a functional group is preferably included in the resin.

By adopting such a configuration, an adhesive layer is fixed to a primer layer by a hydrogen bond and/or an interionic interaction. For this reason, it is possible to suppress planar roughness such as aggregation by securing coating uniformity of the primer layer. In addition, it is possible to more effectively suppress the components constituting an adhesive layer from moving to the primer layer, a curable composition for imprinting which is provided as an upper layer on the primer layer, or a pattern which is a cured product of the curable composition for imprinting. As a result, a substance which can increase the fixing force between the pattern and a mold is less likely to be present in the vicinity of the pattern, and therefore, it is possible to improve the mold releasability of the pattern.

The components constituting an adhesive layer mean components contained in an adhesive layer. For example, components obtained by removing a solvent from the above-described composition for forming an adhesive layer correspond thereto. Similarly, the component constituting a primer layer mean a component contained in a primer layer. For example, components obtained by removing a solvent from the composition for forming a primer layer described above correspond thereto.

In addition, in the present invention, it is preferable that at least one (preferably all) of the components constituting an adhesive layer are substantially insoluble in the solvent contained in the composition for forming a primer layer. The components contained in the composition for forming an adhesive layer may be insoluble in a solvent contained in the composition for forming a primer layer. Components constituting an adhesive layer may be consisting of a cured product of the components contained in the composition for forming an adhesive layer By adopting such a constitution, in a case where a primer layer is formed, it is difficult for components constituting an adhesive layer to be incorporated into the primer layer, and deterioration of the mold releasability of a pattern does not occur. Being substantially insoluble means that components of an adhesive layer which are eluted in a primer layer at the time of forming the primer layer is less than or equal to 10 mass % of total components forming the primer layer. By adopting such a configuration, it is possible to effectively suppress deterioration of the releasability of a mold.

In the present invention, it is preferable that the components constituting an adhesive layer are components which do not substantially thermally diffuse into the primer layer. After a primer layer is formed on the surface of an adhesive layer, in some cases, the adhesive layer may be heated together with the primer layer or the like. However, in a case where components constituting an adhesive layer thermally diffuse in such a heating step, in some cases, the mold releasability of a pattern may deteriorate similarly to the above. In the present invention, such a point is avoided using components which do not substantially thermally diffuse into the primer layer, as the components constituting an adhesive layer. Not being substantially thermally diffusing means that components of an adhesive layer which are eluted in a primer layer after forming the primer layer is less than or equal to 10 mass % of total components forming the primer layer. By adopting such a configuration, it is possible to effectively suppress deterioration of the releasability of a mold.

Examples of the heating in the present invention include: heating for drying a solvent contained in a composition for forming a primer layer in a case of forming a primer layer; or heating for enhancing the reactivity of a curable composition for imprinting in a case of subjecting the curable composition for imprinting to light irradiation. The heating temperature is, for example, 50° C. to 200° C. and preferably 80° C. to 150° C.

Solvents described in paragraph 0059 of JP2014-024322A are exemplified as solvents which may be formulated with a composition for forming an adhesive layer, and the contents thereof are incorporated in the present specification.

In addition, the composition for forming an adhesive layer used in the present invention preferably contains 0.001 to 2.0 mass % of components constituting an adhesive layer and 98.0 to 99.999 mass % of a solvent, and more preferably contains 0.05 to 0.5 mass % of components constituting an adhesive layer and 99.95 to 99.5 mass % of a solvent.

One kind or two or more kinds of each of the components constituting an adhesive layer and the solvents may be contained in the composition for forming an adhesive layer. In a case where the composition for forming an adhesive layer contains two or more kinds thereof, the total amount is preferably within the above-described ranges.

A specific example of the composition for forming an adhesive layer includes a composition for forming an underlayer film for imprinting containing: a solvent (B) and a (meth)acrylic resin (A) which has an ethylenically unsaturated group (P) and a nonionic hydrophilic group (Q) and has a weight-average molecular weight of greater than or equal to 1,000, in which an acid value of the above-described resin (A) is less than 1.0 mmol/g, the composition for forming an underlayer film for imprinting being disclosed in JP2014-024322A. The contents of JP2014-024322A are incorporate into the present specification.

In addition, the disclosure of JP2014-024322A can also be referred to for a method for preparing a composition for forming an adhesive layer, a method for forming an adhesive layer using the above-described composition for forming an adhesive layer, and the like. The contents thereof are incorporate into the present specification.

<Step of Forming Primer Layer on Surface of Adhesive Layer>

In the present invention, it is preferable that a primer layer 13 is formed on the surface of an adhesive layer 12. By forming such a primer layer, it is possible to further improve the filling properties of the curable composition for imprinting on a substrate.

The lower limit value of the thickness of a primer layer is preferably greater than or equal to 1 nm, more preferably greater than or equal to 2 nm, and still more preferably greater than or equal to 3 nm, and still more preferably greater than or equal to 5 nm. In addition, the upper limit value of the thickness of a primer layer is preferably less than or equal to 20 nm and more preferably less than or equal to 15 nm. By setting the film thickness of a primer layer to be greater than or equal to 1 nm, it is possible to further improve wettability of the curable composition for imprinting which will be provided immediately above the primer layer. By setting the film thickness of a primer layer to less than or equal to 20 nm, it is possible to make the residual film after imprinting thinner and more effectively suppress degradation in transferability of a pattern during etching.

In the present invention, the primer layer is usually formed of a composition for forming a primer layer. The composition for forming a primer layer preferably contains a solvent. Specifically, after applying the composition for forming a primer layer onto the surface of an adhesive layer, a solvent is volatilized using heat or through light irradiation to form a thin film. The method for applying a composition for forming a primer layer is not particularly limited, and a disclosure of paragraph 0102 of JP 2010-109092A (the publication number of its corresponding US application is US2011/0199592) can be referred to, and the contents thereof are incorporated in the present specification. In the present invention, a spin coating method or an inkjet method is preferable.

In a case where the composition for forming an adhesive layer which contains a solvent is used in a case of forming an adhesive layer, a primer layer is preferably formed by applying a composition for forming a primer layer after volatilizing (drying) the solvent from the composition for forming an adhesive layer and/or after hardening the adhesive layer. By adopting such a procedure, it is possible to effectively suppress an adhesive layer and a primer layer from being mixed with each other due to a component constituting the primer layer dissolving in a solvent contained in a composition for forming an adhesive layer.

In addition, a method for preparing a composition for forming a primer layer, a method for forming a primer layer formed of the above-described composition for forming a primer layer, and the like can be performed similarly to the method for preparing a composition for forming an adhesive layer and the method for forming an adhesive layer.

In particular, in the present invention, it is preferable that components constituting the above-described adhesive layer are substantially insoluble in the solvent contained in the composition for forming a primer layer. By adopting such a configuration, it is possible to more effectively suppress the deterioration of the mold releasability caused by incorporation of the components of the adhesive layer into the primer layer.

In addition, in the present invention, at least one kind of the component constituting a primer layer preferably includes: a component constituting an adhesive layer; and a functional group capable of forming at least one of a hydrogen bond or an interionic interaction. Examples of the functional group which may be included in the component constituting a primer layer include a hydroxyl group, an amino group, a carbonyl group, and a carboxyl group, and a hydroxyl group is preferable.

Furthermore, as described above, a smallest surface tension at 23° C. of a polymerizable compound among polymerizable compounds contained in the above-described curable composition for imprinting preferably is smaller than a surface tension at 23° C. of at least one kind of polymerizable compound contained in the composition for forming a primer layer. In addition, a smallest surface tension at 23° C. of a polymerizable compound among polymerizable compounds contained in the above-described curable composition for imprinting is smaller than a surface tension at 23° C. of greater than or equal to 90 mass % of the total polymerizable compound contained in the composition for forming a primer layer. Furthermore, a smallest surface tension at 23° C. of a polymerizable compound among polymerizable compounds contained in the above-described curable composition for imprinting is smaller than a surface tension at 23° C. of all polymerizable compounds contained in the composition for forming a primer layer.

By adopting such a configuration, it is possible to improve wettability of the curable composition for imprinting on the surface of a surface layer.

A preferred relationship between the above-described curable composition for imprinting and composition for forming a primer layer is the same as that described in the kit section above.

<Step of Applying Curable Composition for Imprinting onto Surface of Primer Layer>

The present invention includes a step of applying a curable composition for imprinting 14 onto the surface of the primer layer 13 as shown in FIG. 1. The method for applying a curable composition for imprinting is not particularly limited, and a disclosure of paragraph 0102 of JP 2010-109092A (the publication number of its corresponding US application is US2011/0199592) can be referred to, and the contents thereof are incorporated in the present specification. The above-described application is preferably performed through an inkjet method. In addition, the curable composition for imprinting may be applied through multiple coating. In a method for disposing liquid droplets on the surface of a primer layer through an inkjet method or the like, the amount of liquid droplets is preferably about 1 to 20 pL, and the liquid droplets are preferably disposed on the surface of the primer layer at intervals between the liquid droplets. As the intervals between the liquid droplets, intervals of 10 to 1,000 μm are preferable. In the case of the inkjet method, the intervals between the liquid droplets are set as intervals at which inkjet nozzles are disposed.

Furthermore, the volume ratio of the layer-shaped curable composition for imprinting 14 to the primer layer 13 when applied on the substrate is preferably 1:1 to 500, more preferably 1:10 to 300, and still more preferably 1:50 to 200.

<Formation of Pattern>

It is preferable that the pattern forming method to be performed in the present invention further includes: a step of subjecting a curable composition for imprinting, a primer layer, and an adhesive layer to light irradiation in a state in which these are interposed between a substrate and a mold having a pattern to harden the curable composition for imprinting; and a step of peeling the mold. Through such steps, a pattern 15 is obtained as shown in FIG. 1, for example.

Specifically, in order to transfer a desired pattern to a layer-shaped curable composition for imprinting, a mold is brought into press contact with the surface of the layer-shaped curable composition for imprinting. Accordingly, it is possible to transfer a fine pattern previously formed on the pressing surface of the mold to the layer-shaped curable composition for imprinting.

The mold may be a light-transmitting mold or a light non-transmitting mold. In a case where a light-transmitting mold is used, it is preferable to radiate light from the mold side. On the other hand, in a case where a light non-transmitting mold is used, it is preferable to use a light-transmitting substrate as a substrate to radiate light from the substrate side. In the present invention, it is preferable to radiate light from a mold side using a light-transmitting mold.

A mold which can be used in the present invention is a mold having a pattern to be transferred. Regarding the pattern on the above-described mold, it is possible to form a pattern according to a desired processing accuracy, for example, through photolithography, or an electron beam drawing method. In the present invention, the mold pattern forming method is not particularly limited. In addition, it is possible to use a pattern formed through the above-described pattern forming method as a mold.

Materials constituting the light-transmitting mold used in the present invention are not particularly limited, examples thereof include glass, quartz, polymethyl methacrylate (PMMA), a light-transmitting resin such as a polycarbonate resin, a transparent metal vapor deposition film, a flexible film such as polydimethylsiloxane, a photocured film, and a metal film.

Materials of the light non-transmitting mold used in a case where a light-transmitting substrate of the present invention is used are not particularly limited, but may have a predetermined strength. Specific examples thereof include a ceramic material, an vapor deposition film, a magnetic film, a reflective film, a metal substrate of Ni, Cu, Cr, Fe or the like, a substrate of SiC, silicon, silicon nitride, polysilicon, silicon oxide, amorphous silicon, or the like, but are not particularly restricted.

In the above-described pattern forming method, in a case where imprint lithography is performed using a curable composition for imprinting, it is preferable to set the mold pressure to be less than or equal to 10 atm. By setting the mold pressure to be lower than or equal to 10 atm, it is difficult for a mold and a substrate to deform, and the accuracy of pattern formability tends to improve. In addition, it is preferable from the viewpoint that the size of a device tends to be reduced due to low pressurization. The mold pressure is preferably selected from a range within which the uniformity of mold transfer can be secured within a range where a residual film of a curable composition for imprinting of a mold convex portion is reduced.

In the pattern forming method, the irradiation amount of light irradiation in the above-described step of irradiating the curable composition for imprinting with light may be sufficiently larger than the minimum irradiation amount necessary for hardening. The irradiation amount necessary for hardening is appropriately determined by investigating the amount of consumption of unsaturated bonds of the curable composition for imprinting or the like.

In addition, regarding the temperature of a substrate in a case of light irradiation in imprint lithography applied to the present invention, light irradiation is usually performed at room temperature, but may be performed while heating in order to enhance the reactivity. In a case where the environment is kept in a vacuum condition as a preliminary stage of light irradiation, it is effective to prevent air bubbles from being mixed in, suppress a decrease in reactivity due to oxygen mixed in, and improve the adhesiveness between a mold and a curable composition for imprinting. Therefore, light irradiation may be performed in a vacuum condition. In addition, in the pattern forming method, the preferred degree of vacuum at the time of light irradiation is within a range of 10⁻¹ Pa to an atmospheric pressure.

In a case of exposure, it is desirable to set the exposure illuminance to be within a range of 1 mW/cm² to 500 mW/cm².

The above-described pattern forming method may include a step of hardening a layer-shaped curable composition for imprinting (pattern forming layer) through light irradiation, and then, further hardening the hardened pattern by adding heat as necessary. The temperature for heating and hardening a curable composition for imprinting after light irradiation is preferably 150° C. to 280° C. and more preferably 200° C. to 250° C. In addition, the time for applying heat is preferably 5 to 60 minutes and more preferably 15 to 45 minutes.

<Pattern>

A pattern formed through the above-described method for forming a pattern as described above can be used as a permanent film used in a liquid crystal display device (LCD) or the like or an etching resist for manufacturing a semiconductor element (lithography mask).

In addition, it is possible to form a grid pattern on a glass substrate of a liquid crystal display device using the pattern formed through the above-described pattern forming method to manufacture a polarizing plate having a large screen size (for example, 55 inches or larger than 60 inches) with little reflection and absorption at low cost. For example, polarizing plates disclosed in JP2015-132825A or WO2011/132649A can be manufactured. 1 inch is 25.4 mm.

Specifically, the pattern formed in the present invention can be preferably used for producing a recording medium such as a magnetic disk, a light-receiving element such as a solid image pickup element, a light emitting element such as a light emitting diode (LED) or organic electroluminescence (organic EL), an optical device such as a liquid crystal display (LCD) device, a diffraction grating, a relief hologram, optical components such as an optical waveguide, an optical filter, and a microlens array, a thin film transistor, an organic transistor, a color filter, an anti-reflection film, a polarizing plate, a polarizing element, an optical film, flat panel display member such as a column material, a nano-biodevice, an immunological analysis chip, deoxyribonucleic acid (DNA) separation chip, a microreactor, photonic liquid crystal, a guide pattern for forming a fine pattern (directed self-assembly, DSA) using self-assembly of a block copolymer, and the like.

The pattern formed in the present invention is also useful as an etching resist (lithography mask). In a case of using a pattern as an etching resist, a fine pattern is first formed on a substrate, for example, in a nano or micron order through the above-described pattern forming method using a silicon substrate (such as silicon wafer) in which, for example, a thin film of SiO₂ or the like, as a substrate is formed. In the present invention, it is particularly beneficial from the viewpoint that it is possible to form a fine pattern in a nano order, and it is also possible to form a pattern having a size of less than or equal to 50 nm and particularly a size of less than or equal to 30 nm. The lower limit value of the size of the pattern formed through the above-described pattern forming method is not particularly specified, but can be set, for example, to be greater than or equal to 1 nm.

Thereafter, a desired pattern can be formed on a substrate by etching with hydrogen fluoride or the like in a case of wet etching or with etching gas such as CF₄ in a case of dry etching. The pattern has good etching resistance, particularly to dry etching. That is, the pattern formed through the above-described pattern forming method is preferably used as a lithography mask.

### EXAMPLES

Hereinafter, the present invention will be more specifically described with reference to examples. The material, the usage, the proportion, treatment contents, a treatment procedure, and the like shown in Examples below can be appropriately changed without departing from the gist of the present invention. Accordingly, the range in the present invention is not limited to specific examples shown below.

The proportions of each of the components in Tables 1 to 3 are mass ratios.

<Preparation of Compositions for Forming Primer Layer>

As described in Table 1 or 2, components are blended with each other and filtered with a polytetrafluoroethylene (PTFE) filter having a pore diameter of 0.1 μm to prepare compositions for forming a primer layer shown in Examples 1 to 11 and Comparative Examples 1 to 9.

<Preparation of Curable Composition for Imprinting>

Mixtures were prepared by mixing components as described in Table 3 and further adding 200 mass ppm (0.02 mass %) of 4-hydroxy-2,2,6,6-tetramethylpiperidine-1-oxyl free radical (manufactured by Tokyo Chemical Industry Co., Ltd.) thereto as a polymerization inhibitor with respect to the total amount of the polymerizable compound. These were filtered with a PTFE filter having a pore diameter of 0.1 μm to prepare curable compositions for imprinting V-1 to V-5.

<Formation of Adhesive Layer and Primer Layer>

A Silicon wafer was spin-coated with a composition for forming an adhesive layer shown in Example 6 of JP2014-024322A and heated with a hot plate at 220° C. for 1 minute to form an adhesive layer having a thickness of 5 nm. Subsequently, the surface of the adhesive layer was spin-coated with a composition for forming a primer layer and heated with a hot plate at 100° C. for 1 minute to form each primer layer having a thickness described in Table 1 or 2.

<Film Thickness and Film Thickness Stability of Primer Layer>

Predetermined five points of each primer layer obtained above were measured to obtain an average value.

The silicon wafer on which the primer layer is formed was further allowed to stand for 24 hours at 23° C. and the film thickness was measured again. The difference (ΔFT) in film thickness before and after the standing was checked and evaluated as follows.

A: ΔFT ≤0.3 nm

B: 0.3 nm<ΔFT ≤1.0 nm

C: ΔFT >1.0 nm

D: Measurement cannot be performed (for example, a film is aggregated after 24 hours and is not a thin film)

<Measurement of Surface Tension>

Measurement of the surface tension of each compound was performed at 23° C.±0.2° C. using a glass plate using a surface tensiometer SURFACE TENS-IOMETER CBVP-A3 manufactured by Kyowa Interface Science Co., Ltd. The unit is expressed in mN/m.

<Viscosity>

The viscosity was measured by setting the rotational frequency to 50 rpm using an E-type rotational viscometer RE85L manufactured by TOKI SANGYO CO., LTD. and a standard cone rotor (1°34′×R24) and controlling the temperature of a sample cup to 23±0.2° C. The unit is expressed in mPa·s.

<Wettability of Inkjet (U) Liquid Droplets>

Each curable composition for imprinting, which was shown in Table 3 and of which the temperature was adjusted to 23° C. was discharged on the surface of the primer layer obtained above at a small amount of liquid droplet of 6 pL per nozzle using an inkjet printer DMP-2831 manufactured by Fujifilm Dimatix, to coat the surface of the adhesive layer so that liquid droplets are squarely arrayed at an interval of about 880 μm. The droplet shape was imaged 3 seconds after the coating and the droplet diameter was measured.

A: Average diameter of IJ liquid droplets >350 μm

B: 250 μm<average diameter of U liquid droplets ≤350 μm

C: Average diameter of U liquid droplets ≤250 μm

<Release Force>

Any of curable compositions for imprinting V-1 to V-5 of which the temperature was adjusted to 23° C. was discharged on the surface of the primer layer obtained above at an amount of liquid droplet of 6 pL per nozzle using an inkjet printer DMP-2831 manufactured by Fujifilm Dimatix, to coat the surface of the primer layer so that liquid droplets are squarely arrayed at an interval of about 100 μm, and to make a pattern forming layer. Next, a quartz mold (line pattern having a line width of 20 nm and a depth of 50 nm) was brought into press contact with the pattern forming layer in a He atmosphere (substitution rate of greater than or equal to 90 volume %), and the mold was filled with the curable composition for imprinting. A high pressure mercury lamp was used to perform an exposure from the mold side under the condition of 300 mJ/cm² at a point in time 10 seconds have elapsed after pressing. Then, the mold was peeled off to transfer the pattern to the pattern forming layer. The release force required for peeling was measured using a load cell.

A: Release force ≤15 N

B: 15 N<release force ≤20 N

C: 20 N<release force ≤25 N

D: Release force >25 N

<Processing Resistance>

A curable composition for imprinting, of which the temperature was adjusted to 23° C. was discharged on the surface of the primer layer obtained above at a small amount of liquid droplet of 6 pL per nozzle using an inkjet printer DMP-2831 manufactured by Fujifilm Dimatix, to coat the surface of the above-described primer layer so that liquid droplets are squarely arrayed at an interval of about 100 μm. The curable composition for imprinting was formed in a layer shape. Next, a quartz substrate (without a pattern) was brought into press contact with the layer-shaped curable composition for imprinting in a helium atmosphere (substitution rate of greater than or equal to 90 volume %). A high pressure mercury lamp was used to perform an exposure from the mold side under the condition of 300 mJ/cm² at a point in time 10 seconds have elapsed after pressing. Then, the mold was peeled off to obtain a thin film (with a film thickness of about 300 nm) of the curable composition for imprinting.

The above-described sample was introduced into an etching device (Centura-DPS manufactured by APPLIED MATERIALS) to perform etching under the following conditions.

The surface condition of the thin film after the etching was observed with a non-contact type interference microscope.

A: There was no unevenness in film thickness, and the entire surface was etched homogeneously.

B: Boundaries of U liquid droplets in a partial area were excessively etched, and unevenness in film thickness occurred.

C: Boundaries of U liquid droplets were excessively etched over the entire surface, and unevenness in film thickness occurred.

<<Etching Conditions>>

Etching gas: CHF₃/CF₄/O₂/Ar mixed gas

Temperature of substrate during etching: 20° C.

Etching rate: 80 nm/min

TABLE 1

| | | | Surface | | | | | |
|---|---|---|---|---|---|---|---|---|
| | | Viscosity | tension | | | | | |
| | | at 23° C. | (mN/m) | Example 1 | Example 2 | Example 3 | Example 4 | Example 5 |
| A-1 | Diacrylate including bisphenyl | 800 | 41 | 0.3 | | | | |
| | structure | | | | | | | |
| A-2 | Ethoxylated bisphenol F | 680 | 40 | | 0.2 | | | |
| | diacrylate | | | | | | | |
| A-3 | Ethoxylated bisphenol F | 980 | 40 | | | 0.3 | | |
| | diacrylate | | | | | | | |
| A-4 | Ethoxylated bisphenol F | 900 | 41 | | | | 0.3 | 0.2 |
| | diacrylate | | | | | | | |
| A-5 | Pentaerythritol tetraacrylate | 760 | 39 | | | | | |
| A-6 | Ditrimethylolpropane | 1200 | 38 | | | | | |
| | tetraacrylate | | | | | | | |
| A-7 | Dioxane glycol diacrylate | 420 | 38 | | | | | |
| B-1 | Polyethylene glycol | 120 | 44 | | | | | 0.1 |
| B-2 | Trimethylol propane triacrylate | 110 | 34 | | | | | |
| C-1 | Propylene glycol monomethyl | — | — | 99.7 | 99.8 | 99.7 | 89.7 | 89.7 |
| | acetate | | | | | | | |
| C-2 | γ-Butyrolactone | — | — | | | | 10 | |
| C-3 | Cyclohexanone | — | — | | | | | 10 |
| C-4 | 4-Methyl-2-pentanol | — | — | | | | | |

| | | | | | |
|---|---|---|---|---|---|
| Kind of curable composition for imprinting | V-1 | V-1 | V-2 | V-3 | V-4 |
| Film thickness (nm) | 8 | 6 | 8 | 8 | 8 |
| Film thickness stability | A | A | A | A | A |
| Wettability of IJ liquid droplets | A | A | A | A | A |
| Release force | A | A | A | A | A |
| Processing resistance | A | A | A | A | A |

| | | Example 6 | Example 7 | Example 8 | Example 9 | Example 10 | Example 11 |
|---|---|---|---|---|---|---|---|
| A-1 | Diacrylate including bisphenyl | | | | | 0.15 | |
| | structure | | | | | | |
| A-2 | Ethoxylated bisphenol F | | | | | | |
| | diacrylate | | | | | | |
| A-3 | Ethoxylated bisphenol F | | | | | | |
| | diacrylate | | | | | | |
| A-4 | Ethoxylated bisphenol F | 0.15 | | | | | 0.2 |
| | diacrylate | | | | | | |
| A-5 | Pentaerythritol tetraacrylate | | 0.4 | | | | |
| A-6 | Ditrimethylolpropane | | | 0.4 | | | |
| | tetraacrylate | | | | | | |
| A-7 | Dioxane glycol diacrylate | | | | 0.4 | | |
| B-1 | Polyethylene glycol | | | | | 0.35 | |
| B-2 | Trimethylol propane triacrylate | 0.15 | | | | | 0.3 |
| C-1 | Propylene glycol monomethyl | 89.7 | 99.6 | 89.6 | | 99.5 | 99.5 |
| | acetate | | | | | | |
| C-2 | γ-Butyrolactone | | | | 79.6 | | |
| C-3 | Cyclohexanone | | | | 10 | | |
| C-4 | 4-Methyl-2-pentanol | 10 | | 10 | 10 | | |

| | | | | | | |
|---|---|---|---|---|---|---|
| Kind of curable composition for imprinting | V-5 | V-2 | V-1 | V-4 | V-2 | V-1 |
| Film thickness (nm) | 9 | 9 | 10 | 10 | 12 | 13 |
| Film thickness stability | A | A | A | A | A | A |
| Wettability of IJ liquid droplets | A | A | A | A | B | B |
| Release force | A | A | A | A | A | A |
| Processing resistance | A | B | B | B | B | B |

TABLE 2

| | | | Surface | | | | |
|---|---|---|---|---|---|---|---|
| | | Viscosity | tension | Comparative | Comparative | Comparative | Comparative |
| | | at 23° C. | (mN/m) | Example 1 | Example 2 | Example 3 | Example 4 |
| A-4 | Ethoxylated bisphenol F diacrylate | 900 | 41 | | | | |
| A-5 | Pentaerythritol tetraacrylate | 760 | 39 | | | | |
| B-1 | Polyethylene glycol | 120 | 44 | 0.3 | | | |
| B-2 | Trimethylol propane | 110 | 34 | | 0.4 | | |
| | trimethacrylate | | | | | | |
| B-3 | 1,3-Phenylene bis(methylene) | 10 | 40 | | | 1 | |
| | diacrylate | | | | | | |
| B-4 | Polyethylene glycol diacrylate | 22 | 39 | | | | 0.3 |
| B-5 | Tricyclodecane dimethanol | 160 | 38 | | | | |
| | diacrylate | | | | | | |
| B-6 | Acrylate having fluorine skeleton | Solid | | | | | |
| C-1 | Propylene glycol monomethyl | — | — | 99.7 | 89.6 | 89 | 99.7 |
| | ether acetate | | | | | | |
| C-2 | γ-Butyrolactone | — | — | | | 10 | |
| C-3 | Cyclohexanone | — | — | | 10 | | |
| C-4 | 4-Methyl-2-pentanol | — | — | | | | |

| | | | | |
|---|---|---|---|---|
| Kind of curable composition for imprinting | V-1 | V-2 | V-1 | V-3 |
| Film thickness (nm) | 8 | 10 | 10 | 7 |
| Film thickness stability | A | B | D | A |
| Wettability of IJ liquid droplets | A | C | — | A |
| Release force | A | A | — | D |
| Processing resistance | C | B | — | C |

| | | Comparative | Comparative | Comparative | Comparative | Comparative |
|---|---|---|---|---|---|---|
| | | Example 5 | Example 6 | Example 7 | Example 8 | Example 9 |
| A-4 | Ethoxylated bisphenol F diacrylate | | | 0.1 | | 0.1 |
| A-5 | Pentaerythritol tetraacrylate | | | | 0.2 | |
| B-1 | Polyethylene glycol | | | | | 0.4 |
| B-2 | Trimethylol propane | | | 0.3 | | |
| | trimethacrylate | | | | | |
| B-3 | 1,3-Phenylene bis(methylene) | | | | 0.8 | |
| | diacrylate | | | | | |
| B-4 | Polyethylene glycol diacrylate | | | | | |
| B-5 | Tricyclodecane dimethanol | 1 | | | | |
| | diacrylate | | | | | |
| B-6 | Acrylate having fluorine skeleton | | 0.3 | | | |
| C-1 | Propylene glycol monomethyl | 89 | 99.7 | 79.6 | 89 | 99.5 |
| | ether acetate | | | | | |
| C-2 | γ-Butyrolactone | | | | | |
| C-3 | Cyclohexanone | | | | 10 | |
| C-4 | 4-Methyl-2-pentanol | 10 | | 20 | | |

| | | | | | |
|---|---|---|---|---|---|
| Kind of curable composition for imprinting | V-4 | V-1 | V-5 | V-1 | V-5 |
| Film thickness (nm) | 10 | 8 | 10 | 7 | 10 |
| Film thickness stability | D | A | B | D | A |
| Wettability of IJ liquid droplets | — | C | C | — | A |
| Release force | — | A | A | — | A |
| Processing resistance | — | A | B | — | C |

The viscosity at 23° C. and the surface tension in Tables 1 and 2 are a viscosity at 23° C. and a surface tension of each polymerizable compound.

The structures of the compounds described in the above-described tables are as follows.

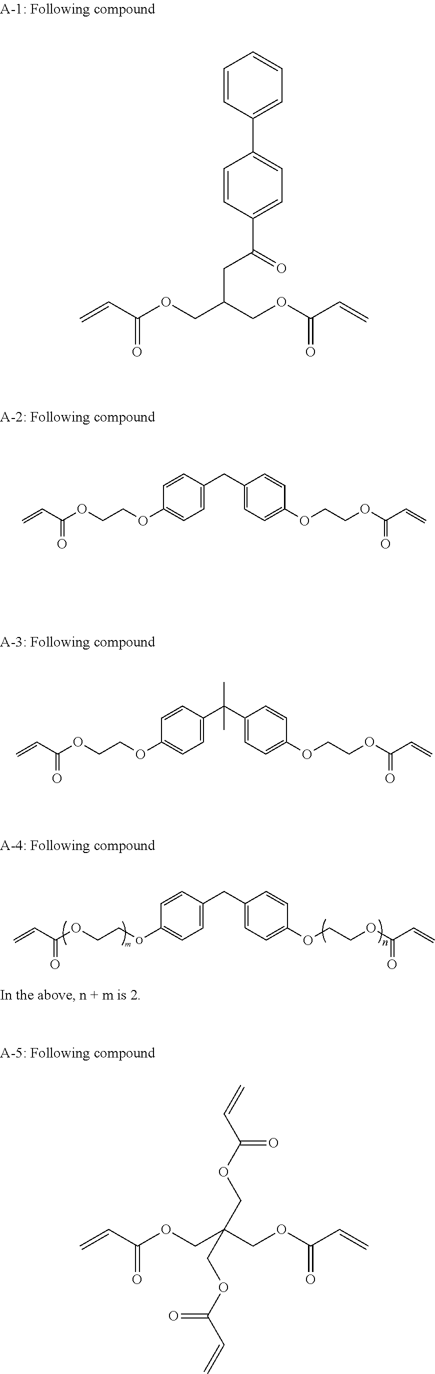

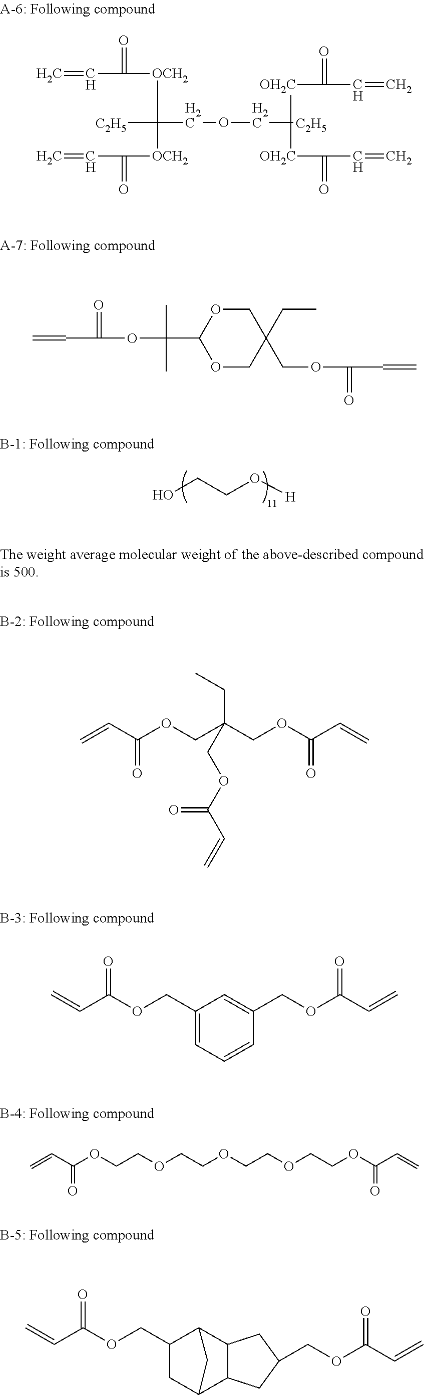

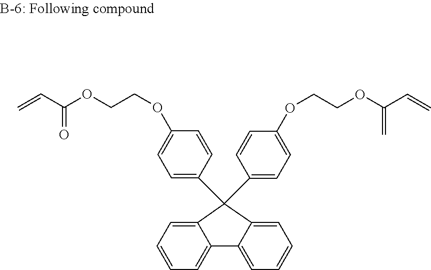 [SMILES: C=CC(=C)OCCOc1ccc(C2(c3ccc(OCCOC(=O)C=C)cc3)c3ccccc3-c3ccccc32)cc1]

The compositions of the curable compositions for imprinting V-1 to V-5 are shown below.

TABLE 3

| | Surface tension | | | | | |
|---|---|---|---|---|---|---|
| | (mN/m) of each | | | | | |
| | polymerizable | | | | | |
| | compound | V-1 | V-2 | V-3 | V-4 | V-5 |
| 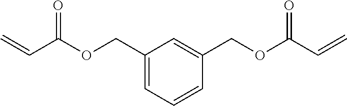 [SMILES: C=CC(=O)OCc1cccc(COC(=O)C=C)c1] | 40 | 60 | 60 | 50 | | 80 |
| 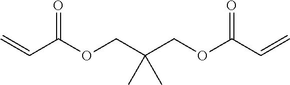 | 31 | 20 | | | | |
| 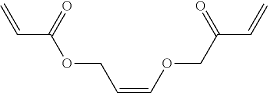 | 35 | | 25 | | | 20 |
| 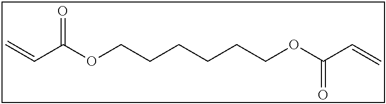 [SMILES: C=CC(=O)OCCCCCCOC(=O)C=C] | 34 | | | | 50 | |
| 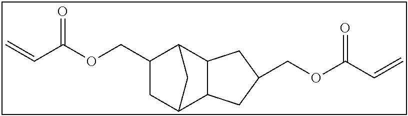 [SMILES: C=CC(=O)OCC1CC2C3CC(COC(=O)C=C)C(C3)C2C1] | 38 | | | | | |
| 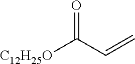 | 29 | 20 | 15 | | | |
| 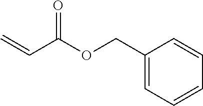 | 37 | | | 40 | 40 | |
| 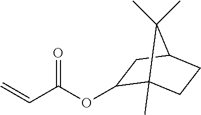 | 30 | | | 10 | 10 | |
| 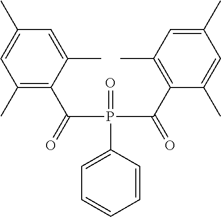 [SMILES: Cc1cc(C)c(C(=O)P(=O)(C(=O)c2c(C)cc(C)cc2C)c2ccccc2)c(C)c1] | | 2 | 2 | 2 | 2 | 2 |
| 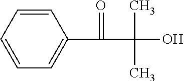 | | | 2 | 2 | 2 | |
| 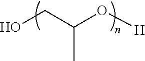 | | 3 | | | | |
| 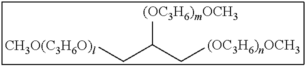 | | | 3 | | | 3 |
| 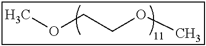 | | | | 1 | | |
| Fluorine surfactant (Capstone FS-3100) | | | | | 3 | |
| Viscosity (mPa · S) of curable composition | | 8 | 7 | 7 | <6 | 10 |
| for imprinting at 23° C. | | | | | | |
| Surface tension (mN/m) of curable | | 33 | 34 | 35 | 32 | 37 |
| composition for imprinting at 23° C. | | | | | | |

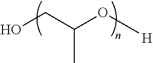

In Table 3, n in the above-described compounds is an integer of 6 to 8.

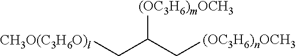

In Table 3, n+m+l in the above-described compounds is 7 to 13.

As is apparent from the above-described results, in the case where the composition for forming a primer layer of the present invention was used, wettability on the primer layer surface of the curable composition for imprinting was excellently improved while maintaining various imprinting performances was obtained.

More specifically, in the case where the composition for forming a primer layer of the present invention is used, a primer layer having excellent film thickness stability can be formed, and the wettability of IJ liquid droplets becomes excellent. Furthermore, the release force of a pattern formed on an upper layer of the primer layer can be reduced and the etching processing resistance can be made excellent.

In particular, it was found that, in a case where the composition for forming a primer layer contains a polymerizable compound containing an aromatic ring, the processing resistance becomes superior.

On the other hand, in a case where a polymerizable compound is not blended or a case where the content of a polymerizable compound is small even through the polymerizable compound is blended (Comparative Examples 1 and 9), the etching processing resistance is inferior.

In addition, in a case where a polymerizable compound having a viscosity out of a range of 200 to 2,000 mPa·s is blended (Comparative Examples 2 to 9), a stable primer layer could not be formed (Comparative Examples 3, 5, and 8), the wettability of U liquid droplets became inferior (Comparative Examples 2, 6, and 7), or the release force of a pattern increased (Comparative Example 4).

### EXPLANATION OF REFERENCES

11: substrate
12: adhesive layer
13: primer layer
14: curable composition for imprinting
15: pattern
21: adhesive layer
22: curable composition for imprinting

What is claimed is:

1. A composition for forming a primer layer which is used for forming a primer layer, the composition comprising:
a polymerizable compound having a viscosity of 200 to 2,000 mPa·s at 23° C.; and
a solvent,
wherein a content of the polymerizable compound in a nonvolatile component contained in the composition is greater than or equal to 30 mass %,
wherein a content of the solvent in the composition is greater than or equal to 98.0 mass %, and
wherein the primer layer is a liquid film in a case where a curable composition for imprinting is applied onto a surface of the primer layer, and the primer layer and the curable composition for imprinting are soluble to each other.

2. The composition for forming a primer layer according to claim 1,
wherein a surface tension of the polymerizable compound at 23° C. is greater than or equal to 38 mN/m.

3. The composition for forming a primer layer according to claim 1,
wherein the polymerizable compound contains an aromatic ring.

4. The composition for forming a primer layer according to claim 1,
wherein the polymerizable compound contains two or more aromatic rings in a molecule.

5. The composition for forming a primer layer according to claim 1, further comprising:
a non-polymerizable alkylene glycol compound.

6. The composition for forming a primer layer according to claim 1,
wherein a proportion of an alkylene oxide chain in the polymerizable compound is less than or equal to 30 mass %, provided that the proportion of the alkylene oxide chain is a value calculated by (formula weight of alkylene oxide chain in polymerizable compound)/(molecular weight of polymerizable compound)×100.

7. A kit comprising:
the composition for forming a primer layer according to claim 1; and
a curable composition for imprinting containing a polymerizable compound.

8. The kit according to claim 7,
wherein a smallest surface tension at 23° C. of a polymerizable compound among polymerizable compounds contained in the curable composition for imprinting is smaller than a surface tension at 23° C. of at least one kind of polymerizable compounds contained in the composition for forming a primer layer.

9. The kit according to claim 7,
wherein a smallest surface tension at 23° C. of a polymerizable compound among polymerizable compounds contained in the curable composition for imprinting is smaller than a surface tension at 23° C. of all of polymerizable compounds contained in the composition for forming a primer layer.

10. The kit according to claim 7,
wherein a content of a solvent in the curable composition for imprinting is less than or equal to 5 mass % of the composition.

11. A primer layer formed of the composition for forming a primer layer according to claim 1.

12. The primer layer according to claim 11,
wherein a thickness of the primer layer is 5 to 20 nm.

13. A laminate comprising:
a primer layer formed of the composition for forming a primer layer according to claim 1; and
a layer formed of a curable composition for imprinting which is positioned at a surface of the primer layer and contains a polymerizable compound.

14. The laminate according to claim 13, further comprising:
an adhesive layer on a surface of the primer layer on a side opposite to a side where the layer formed of the curable composition for imprinting is positioned.
